(19) United States
(12) Patent Application Publication
(10) Pub. No.: US 2009/0032091 A1
(43) Pub. Date: Feb. 5, 2009

(54) Solar cell

(75) Inventors: Wen-Jui Huang, Hsinchu City (TW); Chin-Chang Lin, Hsinchu City (TW)

Correspondence Address: BIRCH STEWART KOLASCH & BIRCH, PO BOX 747, FALLS CHURCH, VA, 22040-0747, US

(73) Assignee: GIGASTORAGE CORPORATION

(21) Appl. No.: 11/902,461

(22) Filed: Sep. 21, 2007

(30) Foreign Application Priority Data
Aug. 3, 2007 (KR) 096128772

(51) Int. Cl. H01L 31/04

(52) U.S. Cl. 136/252

(57) ABSTRACT

A solar cell comprises a substrate with a p-n junction formed therein. A buffer layer is formed on the substrate, wherein the buffer layer has a plurality of grooves formed therein. The material for forming the buffer layer includes silicon oxide, nitride, oxynitride or the combination thereof. The buffer layer is formed by sputtering method. Metal layers are formed onto the buffer layer and filled into the grooves.

### FIELD OF THE INVENTION

The present invention relates to a solar cell, especially relating to a solar cell with buffer layer on the backside of the silicon wafer to reduce the stress of the structure stemming from thinner structure of the solar cell, thereby eliminating the bending effect caused by the stress.

### DESCRIPTION OF THE PRIOR ART

Recently, because of energy shortage, oil price is uprising. Every country endeavors to develop green product; for example, solar cell is the production of this trend. Because of the issues relating to environmental protection, for example, greenhouse effect and oil shortage, the sells of solar cell reaches new height. Solar cell is a kind of optoelectronic semiconductor device for transforming light into electricity; the mechanism of transformation comprises steps list below: solar radiation reaches the surface of solar cell and drives the holes and electrons to p-doped region and n-doped regions respectively, thereby generating electric current and voltage difference between these two areas. Because of high transform efficiency, device can generate voltage difference and output electric current as light radiates on the device. Besides, the transforming efficiency of the solar transforming mechanism is determined by the mobility of electrons and holes and photo-receiving area; wherein, the mobility of the electrons and holes are determined by the materials of solar cell. In other words, the transform efficiency of the solar cell mainly determined by the structure and quality of the p-junction and the n-junction; if a defect exists, the transform efficiency of the solar cell would drop eminently.

The most common material for solar cell is silicon. According to the crystalline structural characters, the type of silicon based on the crystal orientation includes single-crystal, poly-crystal and amorphous silicon and the solar cell formed thereof is named single-crystal silicon solar cell, poly-crystal silicon solar cell and amorphous silicon solar cell, respectively; wherein the highest transform efficiency among them is the single-crystal silicon, the poly-crystal silicon is not easy for cutting, and the amorphous silicon is the cheap one with high growth rate. Under the consideration of transform efficiency, the efficiency of amorphous silicon is too low and the lifetime of the product is too short; therefore, the raw material for solar cell are mainly single-crystal silicon and poly-crystal silicon.

Because silicon crystal is expensive and 90% of solar cell substrate in the world is made by silicon crystal; nowadays, the photovoltaic industry focuses on saving materials and enhancing transform efficiency. Besides that, a metal sheet is typically formed by screen printing on the backside of a solar panel as a connecting circuit for energy transfer. It is because that the metal sheet allows the entering of impurities into the silicon substrate and results in the recombination of electrons and holes, it would make the power of the solar cell loss and lower than expected. To improve efficiency, the contacting area between a solar panel and a conducting metal sheet should be reduced; a practical way is adding an passivation layer between aforementioned layers and forming holes at the position for electrically connecting to reduce the contacting area; for example, Fraunhofer ISE institute, Germany, has manufactured a silicon crystal solar cell with 20.2% transform efficiency; the solar cell adopts laser fired contacts (LFC) process to reduce contacting area; the method includes the steps of evaporating an aluminum layer and insulation layer (passivation layer) on the backside of the solar cell and then driving through the aluminum layer by laser beam for forming the contact. Laser fired contact can effectively solve electricity lose issue and traditional expensive lithography and etching process for forming the holes in the insulation layer are omitted. Though LFC is a low cost, material saving and rapid method, with longer process time, and the laser used in the process is prone to damage the silicon wafer, as well as the metal evaporation issue caused by the high temperature resulted from laser beam, the LFC process is still in development stage.

Laser fired contact can be used for manufacturing solar cell with high transform efficiency on a silicon chip. A solar cell with high efficiency can be applied to space industry as well. The solar cell made by thin silicon chip is too thin to withstand the force applied from bending; therefore, the stability of the whole structure of the solar cell, transform efficiency and reliability is affected.

To solve the problems mentioned above and to meet the demand for manufacturing thin silicon chip for solar cell, the improvement of the solar transform efficiency has became an important task; therefore, the present invention provides a structure to prevent a thin solar chip with high transform efficiency from bending and a method of the same.

### SUMMARY OF THE INVENTION

The object of the present invention is to provide a solar cell with thin structure and high transform efficiency.

Another object of the present invention is to provide a structure preventing a thin solar substrate from bending and a method of the same.

Another object of the present invention is to provide a simplified process for manufacturing a solar cell with large area.

A solar cell includes: a substrate, for example, a wafer for manufacturing a solar cell; a p-n junction formed in the substrate can be made by ion implantation technique to implant ions into the substrate. A buffer layer is formed on the backside of the substrate; wherein, a groove is formed in the buffer layer. A metal layer formed on the buffer layer and fill into the groove. The materials for the buffer layer include silicon dioxide (SiO₂), silicon nitride (SiNₓ), silicon oxynitride layer or their combination. For example, the preferred thickness of the buffer layer is 50˜100 nm. Sputtering is used for forming buffer layer in the present invention.

The groove is formed by laser groove process. In one embodiment, the width of the groove is 10˜40 μm, the depth is 0.6˜6 μm and the interval between the two grooves is 100 to 400 μm. The metal layer mentioned above, including the first metal layer and the second metal layer is formed by a two steps process. The first step uses vaporization, sputtering or hot-immersion coating for forming a first thin metal layer filling in the groove; the second step uses screen printing for forming a thicker second metal layer on the first metal layer; wherein, the thickness of the first metal layer is 1.5˜3.0 μm, the thickness of the second metal layer is 3˜40 μm. The solar cell of the present invention further includes an anti-reflection layer forming on the n-doped area.

### BRIEF DESCRIPTION OF THE DRAWINGS

According to the description below and illustration, it is easy to understand the invention described above and the advantages of the present invention; wherein:

FIG. 1 is the cross section view of the p-n junction in a silicon wafer according to the present invention.

FIG. 2 is the cross section view of depositing a buffer layer on a silicon wafer according to the present invention.

FIG. 3 is the cross section view of several grooves in the buffer layer according to the present invention.

FIG. 4 is the cross section view of depositing the first metal layer on the buffer layer and the wafer according to the present invention.

FIG. 5 is the cross section view of depositing the second metal layer on the first metal layer according to the present invention.

FIG. 6 is the cross section view of forming an anti-reflection layer under the n-doped area according to the present invention.

### DESCRIPTION OF THE PREFERRED EMBODIMENTS

The invention will now be described in greater detail with preferred embodiments of the invention and illustrations attached. Nevertheless, it should be recognized that the preferred embodiments of the invention is only for illustrating. Besides the preferred embodiment mentioned here, present invention can be practiced in a wide range of other embodiments besides those explicitly described, and the scope of the present invention is expressly not limited expect as specified in the accompanying Claims. For description and understanding, the figures are not illustrated according to the real measurement of the embodiment and the details relevant to the present invention are not fully illustrated, too.

The figures are only for illustrating the preferred embodiments of the present invention, not for limiting the present invention. To prevent a miniaturized thin silicon chip of a solar cell from deformation, the present invention discloses a buffer layer made by a special material formed on the backside of silicon chip to change the stress of the structure, strengthen the structure of the solar cell, and ameliorate the capability of releasing the stress or strain.

In one embodiment, the present invention is embodied by changing substrate materials (for example, Cadmium Telluride (CdTe), Gallium Arsenide (GaAs), Indium Gallium Arsenide (InGaAs) . . . etc.) and adopting non-planar surface area for enhancing effective light absorbing area to enhance the transform efficiency of the solar cell, which also encompassed by the aspect of present invention.

The solar cell of the present invention includes: a substrate 100, for example, a silicon wafer 100 for manufacturing a solar cell unit, a p-n junction comprising a p-junction 102 and a n-junction 101, formed on and below the silicon wafer 100, respectively, a buffer layer 103 formed above the backside of the silicon wafer 100 to reduce the stress of the substrate of the thin solar cell. The materials of the buffer layer 103 can be silicon dioxide (SiO₂), silicon nitride (SiNₓ), silicon oxynitride or the combination thereof to reduce stress of the structure and prevent deformation of the structure. For example, preferred thickness of the buffer layer 103 is 50˜100 nm. One feature of the present invention is to form the buffer layer mentioned above by sputtering. A groove 104 is formed in the buffer layer 103. A metal layer includes a first metal layer 105 and a second metal layer 106 is applied on the buffer layer 103; wherein the first metal layer 105 is filled into groove 104 pattern and the second metal layer 106 is disposed above the metal layer 105. Furthermore, referring to FIG. 6, the anti-reflection layer 107 can be selectively formed under the n-doped area 101.

The steps for manufacturing the solar cell of the present invention includes the steps of preparing a substrate, for example, wafer. For example, the wafer mentioned above is the p-type silicon wafer 100; wherein the orientation of crystallization is [100] and the resistivity is 1.2 ohm-cm. The size of the wafer 100 can be decided by its application. For example, the diameter of the silicon wafer is 125 mm when the wafer size is 5 inch, and the diameter of the silicon wafer is 150 mm or 156 mm when the wafer size is 6 inch. The thickness of the silicon wafer 100 is 80˜180 micro-meter.

Then, anisotropic etching, standard photo-lithography, and etch texture process are performed on the silicon wafer 100. The texture is employed to make the silicon wafer 100 with a rough texture to reduce the reflection of the incident light and enhance light extraction efficiency of a solar cell. The ambient temperature of etching solution, for example, sodium hydroxide (NaOH) solution, is about 90° C. After etching, the silicon wafer is immersed in a solution with HF, HCl in sequence for cleaning the wafer, and then the impurities on wafer are washed by de-ionized water.

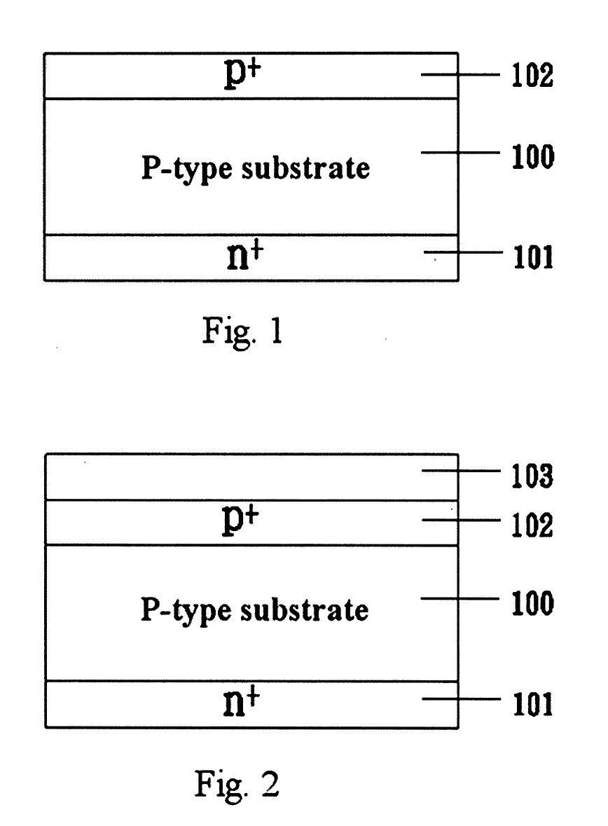

At next step, performing ion implantation to implant n-type ions (for example, phosphate ions) and p-type ions (for example, borate ions) for forming n-type junction 101 and p-type junction 102 in the wafer 100 respectively. Referring to FIG. 1, as a result, a p-n junction of solar cell is finally formed. The implant of the n-type ions can be proceed in diffusion furnaces with POCl₃ and O₂, ambient temperature can be heated to 800˜900° C. by quartz tube or Ni—Cr Wires with three stages.

After the formation of the p-n junctions, anisotropic etching is performed to eliminated oxidized layer (native oxide layer) on wafer 100. The etching solution can be NaOH solution and the ambient temperature is about 90° C. Similarly, after etching, the silicon wafer 100 is cleaned by HF and HCl in sequence. Subsequently, the impurities on the wafer is removed by de-ionized water.

Next, the wafer 100 is placed in the furnace for annealing to diffuse the p-type and n-type ions sited in p-n junctions to improve the uniformity of the doped ions. Similarly, the ambient temperature can be heated to 600˜800° C. by quartz tube or Ni—Cr Wires with three stages.

In next step, referring to FIG. 2, a buffer layer 103 is deposited. The materials of buffer layer 103 comprises silicon dioxide (SiO₂), silicon nitride (SiNₓ), silicon oxynitride or combination thereof. For example, preferred thickness of the buffer layer 103 is 50˜100 nm. The present invention forms the buffer layer by sputtering. For forming the buffer layer 103, the present invention introduces O₂/N₂ into chamber and deposits the buffer layer by Chemical Vapor Deposition (CVD) and Plasma-Enhanced Chemical Vapor Deposition (PECVD) for forming a silicon dioxide layer, silicon nitride layer, silicon oxynitride layer or its combination on silicon wafer 100. The method is expensive; wherein, the gas source comprises SiH₄ (silane), NH₃, N₂, H₂ for forming silicon nitride layer; the silicon nitride layer can be used as an insulation layer and buffer layer. Because of better hardness and water-resistance, a nitride layer is a preferred buffer layer but the dielectric coefficient of this material is slightly higher than other preferred materials.

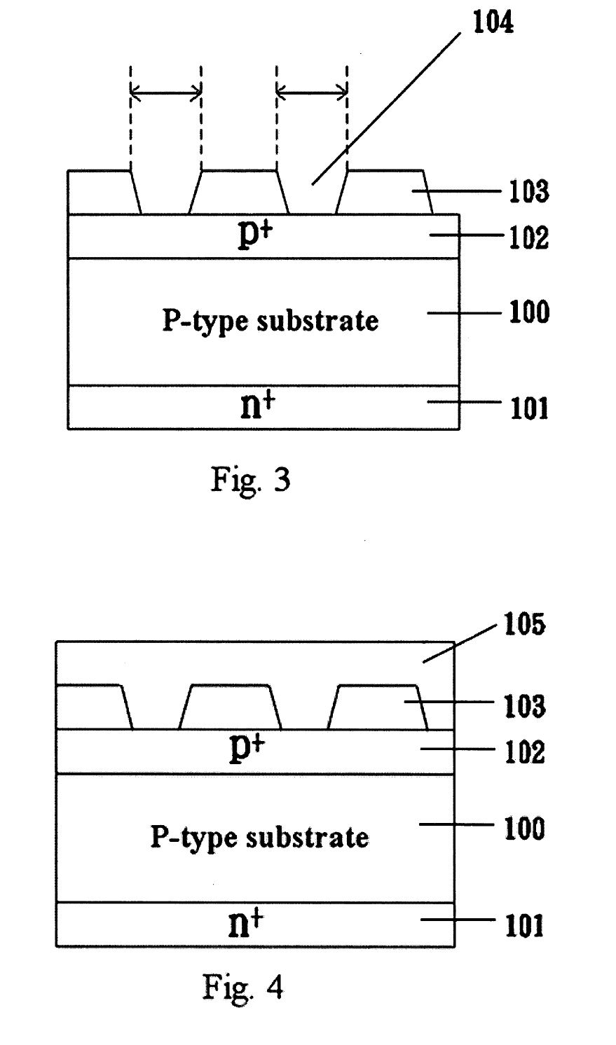

Next, referring to FIG. 3, performing a laser grooving process on buffer layer 103 for forming several groove 104 patterns; in other words, cutting the surface of buffer layer for forming several grooves 104 by a laser, such as a Ar laser with power about 50 W. For example, the width of every groove is 10˜40 μm and the depth is 0.6˜6 μm; furthermore, the groove 104 pattern includes the first grooves and the second grooves; the first grooves spread on the whole surface of the buffer layer in parallel with the intervals between 100 to 400 μm and the second grooves intersect with the first grooves at right angles and interval between each second grooves is 100 to 400 μm. Laser ablation can be proceed by lasers list below: (1) Q-switched ruby laser: the wavelength of this laser is 694 nm with red color, the impulse duration is 20 to 50 n-sec and the output energy reaches 10 J/cm²; (2) Q-switched Alexandrite laser: the wavelength of this invisible laser is 755 nm, the impulse duration is 50 to 100 n-sec and its max frequency is 1 Hz; (3) Q-switched Nd: YAG laser: the wavelength of this invisible laser is 1054 nm and its frequency is 50 kHz; (4) Frequency-doubled Q-switched Nd: YAG laser: the laser beam is generated by letting Q-switched Nd: YAG laser passing through potassium titanyl phosphate (KTP) crystal, the frequency of laser is doubled and the wavelength decrease to 532 nm.

In general, laser grooving process generates buffer layer/silicon debris on the surface of wafer 100 and the walls of groove; therefore, lattice defect or imperfection may exist. A groove cleaning process is necessary after the laser grooving process; buffer layer/silicon debris is solved by solution in the process; the etching solution can be NaOH/KOH solution and the ambient temperature is about 45-60° C. Because NaOH/KOH solution can't etch buffer layer, for example, SiNO₄, if it is desired to etch the side wall of the groove to certain depth, it is necessary to use other kind of etching solution. Similarly, after the etching process, the silicon wafer 100 is cleaned by HF and HCl in sequence and then the impurities on wafer are washed away by de-ionized water.

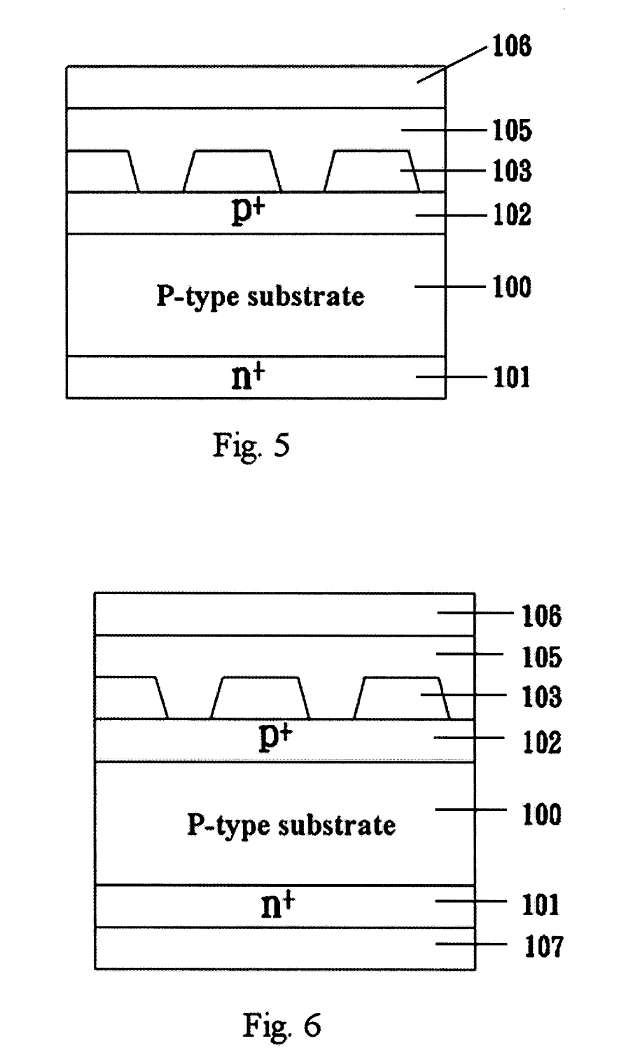

Then, the first metal layer 105 is deposited on the buffer layer 103, the wafers 100 and filled in the groove 104. The materials of the first metal layer 105 comprises aluminum and its alloy; the deposition is proceeded by evaporation or sputtering or by hot-immersion coating a thinner aluminum metal layer; the thickness is about 1.5˜3.0 μm, referring to FIG. 4. Next, depositing the second metal layer 106 on the first metal layer 105, which is done by screen printing on a thicker aluminum metal layer and the thickness is about 3˜40 μm, referring to FIG. 5. In general, the second metal layer 106 is a selective step and the thickness of the second metal layer 106 is much thicker than the thickness of the first metal layer 105. If necessary, de-ionized water is used for removing aluminum dust.

Then, an anti-reflection layer 107 is selectively formed under the n-doped area 101 as shown in FIG. 6. For example, the anti-reflection layer can be formed by CVD, PECVD and the materials for this layer can be cerium oxide (CeO₂), aluminum oxide (Al₂O₃), silicon nitride (Si₃N₄), silicon nitride-titanium dioxide (SiO₂—TiO₂). The thickness of the anti-reflection layer is about 0.05˜0.1 μm.

As mentioned above, the thickness of the miniaturized thin silicon chip in the solar cell structure is about 80˜180 micro-meter; because the thickness of a wafer is too thin to withstand the force applied on it, deformation of the structure is inevitable. The present invention forms a buffer layer 103 on the backside of wafer 100 to change the structure of a thin silicon substrate.

Then, an aluminum sintering is applied to decrease the broken bond (i.e. the so-called dangling bond) of silicon, in wafer and, therefore, the consistency of the solar cell p-n junction is increased. One embodiment of the present invention is to place a silicon wafer in a silicon tube and heating to certain temperature, for example, 400˜500° C., and inducing H₂/N₂ gas for at least 25 minutes. The energy state of foregoing dangling bond is located at the intermediate location the energy gap; because the dangling bond only has one electron, the dangling bond may lost the electron or capture another electron, thereby generating the defect. It is the root to cause electron-hole recombination that would render the lifetime of carriers shortened and the characters of the material worsened; for example, the electrons or holes released by the doped phosphate or borate may be trapped by the defect; which would render the conductivity degrade and, therefore, p-n junctions is vanished.

For the same reason, after the aluminum metal sintering process is finished, the wafer is immersed in HF, HCl in sequence for further cleaning and then the impurities on wafer will be washed by de-ionized water.

Although preferred embodiments of the present invention have been described, it will be understood by those skilled in the art that the present invention should not be limited to the described preferred embodiments. Rather, various changes and modifications can be made within the spirit and scope of the present invention, as defined by the following Claims.

What is claimed is:

1. A solar cell, comprises:
a substrate including p-n junction formed therein;
a buffer layer formed on the backside of said substrate, wherein a groove is formed in said buffer layer; and
a metal layer attached on said buffer layer and filled into said groove.

2. The solar cell of claim 1, wherein said substrate includes a silicon wafer.

3. The solar cell of claim 1, wherein the materials of said buffer layer includes silicon dioxide, silicon nitride, silicon oxynitride or the combination thereof.

4. The solar cell of claim 1, wherein the thickness of said buffer layer is 50˜100 nm.

5. The solar cell of claim 1, wherein said groove is formed by laser grooving process.

6. The solar cell of claim 5, wherein said laser include Ar laser, Q-switched ruby laser, Q-switched Alexandrite laser, Q-switched Nd: YAG laser or Frequency-doubled Q-switched Nd/YAG laser.

7. The solar cell of claim 1, wherein the width of said groove is 10˜40 μm, the depth is 0.6˜6 μm and the interval between said groove is 100 to 400 μm.

8. The solar cell of claim 1, wherein said metal layer is made by aluminum metal or aluminum alloy.

9. The solar cell of claim 1, wherein said metal layer comprising the first metal layer and the second metal layer.

10. The solar cell of claim 9, wherein said first metal layer is formed by vaporization, sputtering or hot immersion.

11. The solar cell of claim 9, wherein said second metal layer is formed by screen printing on said first metal layer.

12. The solar cell of claim 9, wherein the thickness of said first metal layer is 1.5˜3.0 μm, and the thickness of said second metal layer is 3˜40 μm.

13. The solar cell of claim 1, further comprising an anti-reflection layer formed under the n-doped area.

14. The solar cell of claim 13, wherein the materials of said anti-reflection layer including cerium oxide, aluminum oxide, silicon nitride or silicon nitride-titanium dioxide.
